(19) United States
(12) Patent Application Publication
(10) Pub. No.: US 2006/0157225 A1
(43) Pub. Date: Jul. 20, 2006

(54) High turbulence heat exchanger

(76) Inventors: Yves Martin, Ossining, NY (US); Theodore G. van Kessel, Millbrook, NY (US)

Correspondence Address: MOSER, PATTERSON & SHERIDAN LLP;IBM CORPORATION, 595 SHREWSBURY AVE, SUITE 100, SHREWSBURY, NJ, 07702, US

(21) Appl. No.: 11/037,918

(22) Filed: Jan. 18, 2005

(51) Int. Cl. H05K 7/20

(52) U.S. Cl. 165/80.4; 361/699

(57) ABSTRACT

The present invention is a method and apparatus for cooling a heat source. In one embodiment a heat exchanger is provided and includes a channel for receiving a coolant, the channel having a first surface and an opposing second surface. A mesh plug is disposed in the channel for turbulently mixing the coolant within the channel. The first surface of the channel is disposed proximate a semiconductor heat source. In one embodiment the first surface comprises plastic. In one embodiment, the second surface comprises metal, for example, copper. In one embodiment the mesh plug comprises a nickel-coated copper mesh.

### GOVERNMENT RIGHTS IN THIS INVENTION

This invention was made with U.S. government support under contract number H98230-04-C-0920 from the Maryland Procurement Office. The U.S. government has certain rights in this invention.

### BACKGROUND

The present invention relates generally to microprocessor and integrated circuits, and relates more particularly to the cooling of integrated circuit (IC) chips. Specifically, the present invention relates to a heat exchanger for chip cooling.

Efficient cooling of IC devices is essential to prevent failure due to excessive heating. As the number of CMOS devices per chip and clock speeds have increased, such efficient cooling has become an even more prominent concern. For example, while the current generation of microprocessors generate heat on the order of 100 W/cm2, the next generation computer microprocessors are expected to reach heat generation levels of 200 W/cm2 or more.

Conventionally, IC chips are cooled by a heat exchange mechanism, or heat sink, having a thermally conductive plate coupled to the chip. The plate typically has a plurality of raised fins extending from one surface of the plate. The plate and fins conduct heat and increase the surface area over which air may flow, thereby increasing the rate of heat transfer from the heat sink to the surrounding air.

Such air-cooled methods have generally proven to be reliable in facilitating heat transfer for current chips. However, it is generally concluded that current methods of forced air cooling have reached their limits of performance. As such, the trend towards smaller, more powerful chips that generate even greater amounts of heat makes continued reliance on conventional air-cooled methods inadequate.

Thus, there is a need for a heat exchange apparatus that is capable of providing enhanced thermal transfer between a chip and a heat sink.

### SUMMARY OF THE INVENTION

The present invention is a method and apparatus for cooling a semiconductor heat source. In one embodiment a heat exchanger is provided and includes a channel for receiving a coolant, the channel having a first surface and an opposing second surface. A mesh plug is disposed in the channel for turbulently mixing the coolant within the channel. The first surface of the channel is disposed proximate a semiconductor heat source. In one embodiment the first surface comprises plastic. In one embodiment, the second surface comprises metal, for example, copper. In one embodiment the mesh plug comprises a nickel-coated copper mesh.

In another embodiment, a method for cooling a semiconductor heat source is provided. The method includes providing a heat exchanger having a channel for receiving a coolant, the channel having a first surface, an opposing second surface, and a mesh plug disposed therebetween for turbulently mixing the coolant within the channel, wherein the first surface of the channel is disposed proximate the semiconductor heat source. A coolant, for example water, is flowed through the channel.

### BRIEF DESCRIPTION OF THE DRAWINGS

So that the manner in which the above recited embodiments of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a cross-sectional view of one embodiment of a heat exchanger according to the present invention;

FIG. 2 illustrates a cross-sectional view of another embodiment of a heat exchanger according to the present invention;

FIG. 3 illustrates a cross-sectional view of another embodiment of a heat exchanger according to the present invention; and

FIG. 4 illustrates a chart of thermal resistance versus mesh density for a heat exchanger according to the present invention.

To facilitate understanding, identical reference numerals have been used, where possible, to designate identical elements that are common to the figures.

### DETAILED DESCRIPTION

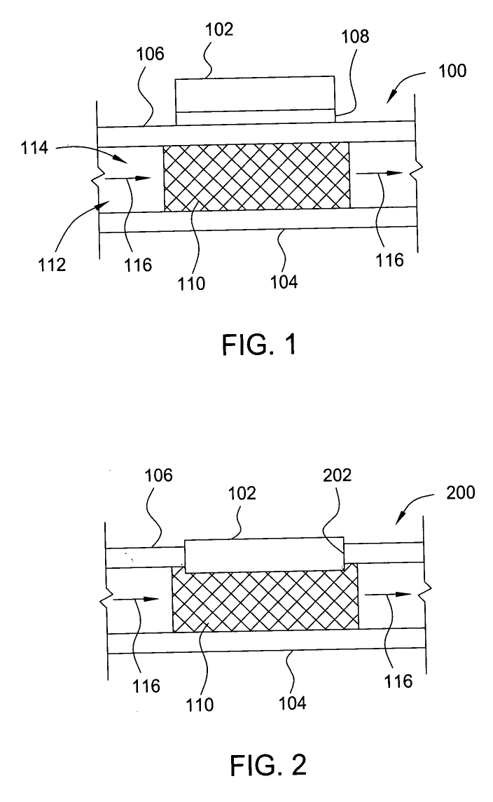

FIG. 1 depicts a cross-sectional view of one embodiment of a heat exchanger 100. The heat exchanger 100 generally includes a first surface 106 disposed in a spaced-apart relation to a second surface 104 and defining a fluid flow channel 114 for the flow of a coolant 112 therebetween. A porous mesh plug 110 is disposed within at least a portion of the fluid flow channel 114 and is in contact with both the first surface 106 and the second surface 104.

A semiconductor heat source 102 is thermally coupled to the first surface 106 of the heat exchanger 100 proximate the mesh plug 110 using any conventional means, such as thermal paste, soldering, bonding, adhesive, and the like. The semiconductor heat source 102 is defined herein as an integrated circuit (IC) chip, a portion of a chip, a plurality or array of chips, a circuit board or portion thereof, any material that is heated through the operation of a semiconductor device or devices, any combination of the preceding, and the like.

A thermal interface 108 comprising, for example, solder, thermally conductive adhesive, thermally conductive paste, liquid metal thermal interface (e.g., at least one of: gallium, indium, tin, and bismuth), and the like, may optionally be disposed between the heat source 102 and first surface 106 of the heat exchanger 100 in order to increase the rate of heat transfer therebetween. A heat exchange fluid, or coolant, 112 flows through the channel 114.

Alternatively, and as depicted in FIG. 2, the first surface 106 may further comprise an aperture 202 sized accordingly to allow the heat source 102 to be placed into direct contact with the mesh plug 110 and the coolant 112 within the channel 114. In embodiments where the first surface contains an aperture 202, the interface between the aperture 202 and the heat source 102 may be sealed by any conventional means, for example by affixing the heat source within the aperture 202 with an epoxy.

The first surface 106 may be any thermally conductive or thermally non-conductive material compatible with process conditions. In the embodiment depicted in FIG. 1, the first surface 106 is thermally conductive at least in a region disposed proximate the heat source 102 to facilitate the transfer of heat from the heat source 102 to the coolant 112 flowing in the channel 114. It is contemplated that the first surface 106 may comprise a highly thermally conductive material solely in the region proximate the heat source 102 and may comprise other materials in other regions.

For example, the first surface 106 may comprise a metal. In one embodiment, the first surface comprises at least one of copper and aluminum. Optionally, a coating (not shown) may be disposed on the first surface 106 on a side facing the channel 114. The coating generally protects the first surface 106 from deterioration due to exposure to the atmosphere, the coolant 112, or other contaminants that may be present in the channel 114.

In the embodiment depicted in FIG. 2, where the heat source 102 is disposed in the aperture 208, the first surface 106 may comprise any material compatible with the process conditions, such as the materials described with respect to the second surface 104, below.

The second surface 104 may comprise any material compatible with the process conditions and may be thermally conductive or thermally non-conductive. In one embodiment, the second surface 104 comprises a plastic. For example, the second surface 104 may comprise polycarbonate, acrylic, or polyethylene.

The mesh plug 110 is disposed in at least a portion of the channel 114 and is in contact with both the first surface 106 and second surface 104, e.g., the mesh plug 110 fills the cross-sectional area of the channel 114. The mesh plug 110 disrupts the laminar flow of the coolant 112 within the channel 114 and along the boundary layer thereby causing turbulent mixing of the coolant 112 and enhancing the rate of heat transfer from the heat source 102 to the coolant 112. As such, the mesh plug 110 is generally disposed at least in the region proximate the heat source 102 and is generally at least as long as the portion of the heat source 102 in contact with the first surface 106. For example, the mesh length and width may be slightly larger (about one or two millimeters) than the lateral dimensions of the heat source 102.

As used herein, the term “mesh” refers to the structural arrangement of the material comprising the mesh plug 110 and includes woven and non-woven webs or screens, porous or sponge-like solids, a matrix of filaments, strands, fibers, or particles, or any other material form that provides a mechanically compliant structure and has sufficient porosity for the coolant 112 to flow through the mesh plug 110. The mesh plug 110 is employed to disrupt the flow of the coolant 112 and cause fluid turbulence. The aperture size and wetted surface area of the mesh plug 110 will vary according to the material used. For example, a reduced aperture size (i.e., more obstructions in the channel 114) generally increases the turbulence of the flow of the coolant 112 but also increases the pressure required to move the coolant 112. Increasing the volume of the flow reduces the pressure required to move a given volume of coolant 112 at the cost of a larger apparatus. As such, the size of the channel 114 and the density of the mesh 110 will vary depending upon the particular application and will depend upon factors such as the coolant 112 and the quantity of heat to be removed per unit time from the heat source 102. A typical volume fraction for the mesh plug 110 will range from about 15 percent to about 45 percent in the active region of the device (i.e., in the region where the mesh plug 110 is employed). However, it is contemplated that other volume fractions may be utilized dependent upon the application, i.e., the material of the coolant 112 and the heat transfer requirements.

The mesh plug 110 may be made of metal or organic materials compatible with the coolant 112, e.g., the mesh plug 110 may be inert with respect to the coolant 112 or reactive with the coolant 112 in a manner that does not substantially degrade the structural or thermal properties of the components of the heat exchanger 100 or otherwise harm the heat source 102. Alternatively, the mesh plug 110 may comprise a material incompatible with the coolant 112, in which case the mesh plug 110 may further comprise a coating that is compatible with the coolant 112, as further described below.

The mesh plug 110 may have a thermal conductivity greater than, equal to, or less than the thermal conductivity of the coolant 112. In one embodiment, the mesh plug 110 comprises at least one of copper, chromium, iron, nickel, stainless steel, tantalum, titanium, and tungsten wire. Alternatively or in combination, the mesh plug 110 may comprise carbon fiber or fiberglass. Typical wire or fiber diameters may be from about 50 to about 100 microns. In one embodiment, the mesh plug 110 comprises a metal wire mesh plug. In one embodiment, the mesh plug 110 comprises a copper or tungsten wire mesh plug. In another embodiment, the mesh plug 110 may comprise glass wool or a glass mesh plug. Other suitable materials include copper wool, porous graphite, machined graphite, electroformed nickel, and the like.

In embodiments where the mesh plug 110 is thermally conductive, the intimate contact between the mesh plug 110 and the first surface 106 and the second surface 104 further enhances heat transfer via continuous thermally conductive paths through the mesh plug 110. Optionally, the elements of the mesh plug 110 may be bonded together, for example by soldering, to further increase the thermal conductivity of the mesh plug 110. The mesh plug 110 may also optionally be soldered to the first surface 106 and/or the second surface 104.

The mesh plug 110 may further comprise an optional coating (not shown). The optional coating protects the mesh plug 110 from any incompatibility with the coolant 112. For example, in one embodiment, the metal mesh plug 110 may comprise copper with a chromium or nickel coating that protects the copper from a coolant 112 comprising water. It is contemplated that the coating may be formed over a mesh plug 110 that is compatible with the coolant 112. It is further contemplated that multiple coatings may be disposed over the mesh plug 110.

The coatings may be applied by conventional means, such as by evaporation, sputtering, plating, chemical vapor deposition, and the like. The thickness of the coating or coatings is chosen for robustness in the presence of the coolant 112 and generally will depend upon the material comprising the coating, the method of application, and the coverage required to achieve the intended purpose of the coating.

Optionally, a similar coating or coatings (not shown) may be disposed on one or more of the heat source 102, first surface 106 and/or second surface 104 where desired to improve compatibility between the coolant 112 and the materials comprising the heat source 102, first surface 106 and/or second surface 104. The coating may also be selected to enhance the adhesion of subsequent layers, to act as an oxidation prevention layer, or to enhance the wettability of the coolant 112 with respect to the surface of the heat source 102, first surface 106 and/or second surface 104. It is contemplated that multiple coatings may be provided, for example, a first coating that is compatible with the coolant 112, and a second coating that enhances wettability of the coolant 112. For example, in one embodiment, a chromium coating is disposed over the second surface 104. A second coating of either gold or platinum may optionally be disposed over the chromium to act, for example, as an oxidation prevention layer. In one embodiment, the chromium coating may be formed to a thickness of about 2500 angstroms. In one embodiment, the gold or platinum coating may be formed to a thickness of about 300 angstroms.

The coolant 112 flows through the channel 114 as indicated by arrows 116. The coolant 112 weaves turbulently between the elements of the mesh plug 110 and is additionally in contact with the first surface 106 and the second surface 104. In embodiments where the heat source 102 is disposed in an aperture formed in the first surface, the coolant is in direct contact with the heat source 102 (see, e.g., FIG. 2). The coolant 112 may be any relatively thermally conductive liquid or liquid mixture that may flow readily and turbulently through the mesh plug 110. For example, the coolant 112 may comprise water, a water-based liquid, or a liquid with a freezing point below that of water. Other suitable liquids include, but are not limited to: alcohols, glycols, ethylene glycol, propylene glycol, sodium chloride, oils, hydrocarbons, hydrocarbon blends, methyl bis(phenylmethyl)-benzene, silicone (e.g., DYNALENE® family of heat transfer fluids and the like), liquid metals, and the like. Liquid metals may comprise at least one of: bismuth, gallium, indium, mercury, tin, and the like. For example, in one embodiment, the coolant 112 is a gallium-indium alloy or a gallium indium tin alloy. In another embodiment, the coolant 112 is water.

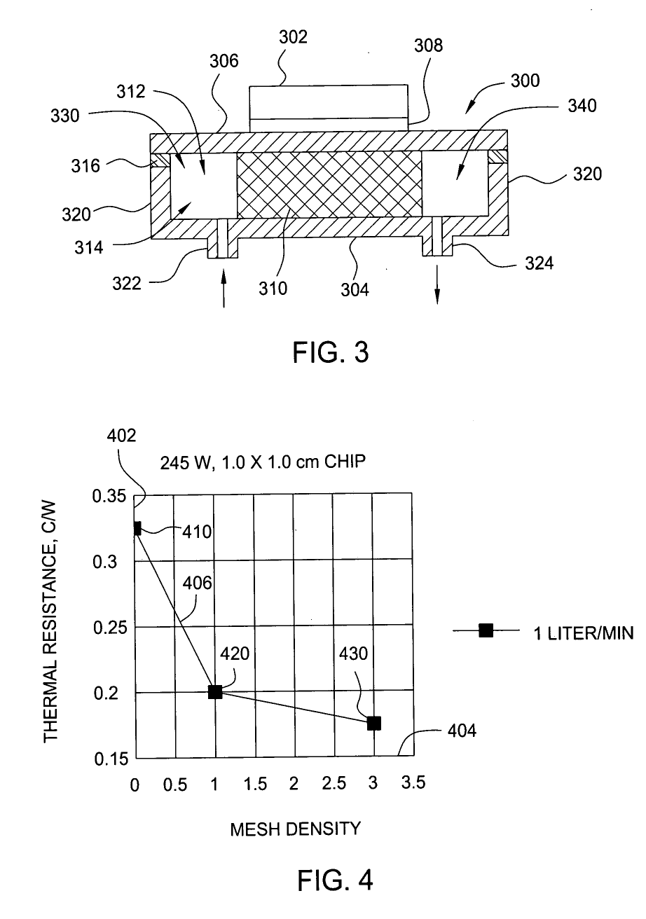

FIG. 3 depicts one exemplary embodiment of a heat exchanger 300. The heat exchanger 300 includes a fluid flow channel 314 defined between a nickel or chrome coated copper first surface 306 and an opposing plastic second surface 304. A nickel coated copper mesh plug 310 is disposed in the channel 314. The first and second surfaces 306, 304 are maintained in a spaced apart relation by a wall disposed therebetween or by peripheral extensions that may be formed in one or more of the first or the second surface 306, 304. In the embodiment depicted in FIG. 3, the first and second surfaces 306, 304 are maintained in a spaced apart relation by peripheral extensions 320 formed in the second surface 304.

At least one inlet 322 and at least one outlet 324 are coupled to the heat exchanger 300 to allow for the introduction and evacuation of a coolant 312 from the channel 314. The inlet 322 and the outlet 324 may be formed in, or coupled to, at least one of: the first surface 306, the second surface 304, and the wall separating the two (e.g., the peripheral extensions 320 in FIG. 3). In the embodiment depicted in FIG. 3, the inlet 322 and the outlet 324 are disposed in the second surface 304.

Where multiple inlets 322 and outlets 324 are used to control the flow of the coolant 312 through the channel 314, the inlets 322 and the outlets 324 may be arranged within manifolds or headers. For example, in the embodiment depicted in FIG. 3, an inlet manifold 330 is formed in the open space defined by the first surface 306, second surface 304, peripheral extensions 320, and one side of the mesh plug 310. The inlet manifold 330 has multiple inlets 322 (only one shown in cross-section). Similarly, an outlet manifold 340 is formed in the open space defined by the first surface 306, second surface 304, peripheral extensions 320, and another side of the mesh plug 310. The outlet manifold 340 has multiple outlets 324 (only one shown in cross-section). The inlet and outlet manifolds 330, 340 are utilized to control the pressure distribution and flow of the coolant 312 through the channel 314.

The coolant 312 may be provided from a coolant source (not shown) and pumped into the inlet 322 of the channel 314 via a pump (not shown). The coolant 312 may be routed from the outlet 324 to a drain or other collection device. Alternatively, the pump may recirculate the coolant 312 from the outlet 324 to the inlet 322 and back through the channel 314. The coolant 312 may optionally be cooled prior to and/or during operation of the heat exchanger 300.

The components of the heat exchanger 300 may be fastened together by any conventional means, such as adhering, bonding, gluing, press fitting, bolting, clamping, and the like. A gasket 316 may be disposed between the seams to further protect against leakage of the coolant 312 from the channel 314. The gasket 316 may be formed as part of the first surface 306, part of the second surface 304, or may be an independent part. In the embodiment depicted in FIG. 3, the first and second surfaces 306, 304 are bolted together by a plurality of bolts (not shown) and a gasket 316 is disposed between the extensions 320 and the first surface 306 to seal the joint therebetween. In one embodiment, the gasket 316 comprises a soft material, such as nylon, polytetrafluoroethylene (PTFE), rubber, silicone, fluoroelastomers (e.g., VITON®), and the like.

A semiconductor heat source 302, e.g., an IC chip, is thermally coupled to the first surface 306 of the heat exchanger 300 using a thermal interface 308. In one embodiment, the thermal interface 308 comprises a liquid metal gallium indium tin eutectic. In operation the coolant 312 flows through the channel 314. The mesh plug 310 causes the coolant 312 to turbulently mix as it flows therethrough. The turbulent mixing of the coolant 312 enhances the heat transfer between the heat source 302 and the

FIG. 4 illustrates a graph 400 of thermal resistance in C/W (measured from the temperature at heat source at the top of the chip relative to the inlet temperature of the water coolant and shown on axis 402) versus the density of the mesh plug 110 in arbitrary units (axis 404) for a 1.0 by 1.0 cm IC chip operating at 245 W with a 1 liter/minute coolant flow (line 406) using water. As can be seen from the graph 400, the thermal resistance drops dramatically as the density of the mesh plug 110 increases. Specifically, data point 410 indicates a thermal resistance of about 0.32 C/W at a mesh density of 0 (indicating no mesh present in the channel). Data point 420 indicates a reduction in thermal resistance to about .2 C/W at an arbitrary, unitized mesh density of 1. Data point 430 indicates a further reduction in the thermal resistance to about 0.16 C/W for a mesh density of 3 (indicating a mesh 3 times as dense as the mesh of data point 420). Hence, an inventive heat exchanger has been disclosed demonstrating heat exchange performance of .16 cm²C/W. Such heat exchange performance is suitable for cooling IC chips generating 200 W or more.

Although the heat exchangers in FIGS. 1 through 3 are depicted as being rectangular, it is contemplated that other geometries may be utilized while adhering to the teachings disclosed herein. For example, an oval conduit may define the fluid flow channel wherein the opposing sides of the conduit may define the first surface and the second surface. It is further contemplated that the teachings disclosed in any of the embodiments above may be combined to the extent not incompatible.

Thus, a heat exchanger is disclosed that facilitates improved heat transfer away from a heat source, such as an IC chip, thereby allowing the IC device to operate more reliably and efficiently than IC chips cooled by conventional methods. Furthermore, the inventive heat exchanger is economical and may be easily fabricated.

While foregoing is directed to the preferred embodiment of the present invention, other and further embodiments of the invention may be devised without departing from the basic scope thereof, and the scope thereof is determined by the claims that follow.

1. A heat exchanger, comprising:
a channel for receiving a coolant, the channel having a first surface and an opposing second surface; and
a mesh plug disposed in the channel for turbulently mixing the coolant within the channel, wherein the first surface of the channel is disposed proximate a semiconductor heat source.

2. The heat exchanger of claim 1, wherein the second surface comprises plastic.

3. The heat exchanger of claim 1, wherein the second surface comprises one of: polycarbonate, acrylic, and polyethylene.

4. The heat exchanger of claim 1 further comprising:
an aperture formed through the first surface for receiving the heat source therein.

5. The heat exchanger of claim 1, wherein the first surface is metal.

6. The heat exchanger of claim 1, wherein the first surface is at least one of: copper and aluminum.

7. The heat exchanger of claim 1, further comprising:
a coating formed on the first surface.

8. The heat exchanger of claim 7, wherein the coating comprises at least one of: chromium, gold, nickel, and platinum.

9. The heat exchanger of claim 1, wherein the mesh plug comprises at least one of: copper, chromium, iron, nickel, stainless steel, tungsten, tantalum, and titanium wire.

10. The heat exchanger of claim 1, wherein the mesh plug comprises at least one of: carbon fiber, glass wool, and a glass mesh plug.

11. The heat exchanger of claim 1, wherein the mesh plug comprises at least one of: copper wool, porous graphite, machined graphite, sintered metal particles, and electroformed nickel.

12. The heat exchanger of claim 1, wherein the mesh plug comprises a metal.

13. The heat exchanger of claim 12, wherein elements of the mesh plug are solder bonded together.

14. The heat exchanger of claim 12, wherein the mesh plug is solder bonded to at least one of: the heat source, the first surface, and the second surface.

15. The heat exchanger of claim 1, wherein elements of the mesh plug are bonded together.

16. The heat exchanger of claim 15, wherein elements of the mesh are bonded together with an organic adhesive.

17. The heat exchanger of claim 1, wherein the mesh plug further comprises:
a coating disposed over the elements of the mesh plug.

18. The heat exchanger of claim 17, wherein the coating comprises at least one of: chromium, gold, nickel and platinum.

19. The heat exchanger of claim 1, further comprising:
an inlet and an outlet fluidly coupled to the channel for the introduction and evacuation of the coolant to and from the channel.

20. The heat exchanger of claim 19, further comprising:
a pump coupled to the inlet for pumping the coolant into the channel.

21. The heat exchanger of claim 20, wherein the outlet is coupled to the pump and the pump is adapted to pump the coolant from the outlet to the inlet.

22. The heat exchanger of claim 1, further comprising:
a gasket disposed between the first surface and the second surface.

23. The heat exchanger of claim 22, wherein the gasket is formed as part of the first surface.

24. The heat exchanger of claim 22, wherein the gasket is formed as part of the second surface.

25. The heat exchanger of claim 22, wherein the gasket comprises at least one of: a fluoroelastomer, polytetrafluoroethylene, nylon, silicone, and rubber.

26. The heat exchanger of claim 22, wherein the gasket comprises a plastic.

27. The heat exchanger of claim 1, further comprising:
a thermal interface disposed between the first surface and the heat source.

28. The heat exchanger of claim 27, wherein the thermal interface comprises a solder thermal interface.

29. The heat exchanger of claim 27, wherein the thermal interface comprises a liquid metal thermal interface.

30. The heat exchanger of claim 27, wherein the thermal interface comprises a at least one of gallium, indium, tin, and bismuth.

31. The heat exchanger of claim 27, wherein the thermal interface comprises gallium indium tin alloy.

32. The heat exchanger of claim 27, wherein the thermal interface comprises a thermal paste.

33. The heat exchanger of claim 1, further comprising;
an inlet manifold and an outlet manifold fluidly coupled to the channel for the introduction and evacuation of the coolant from multiple points across the channel.

34. The heat exchanger of claim 1, further comprising:
an inlet and an outlet fluidly coupled to the channel for the introduction and evacuation of the coolant from the channel;
a thermal interface disposed between the first surface and the heat source; and
wherein the first surface comprises copper having a coating of nickel disposed thereon, and the second surface comprises plastic.

35. The heat exchanger of claim 1, further comprising:
the coolant, wherein the coolant comprises at least one of: water, a water-based liquid, glycol, ethylene glycol, polyethylene glycol, oil, hydrocarbon, hydrocarbon blends, alcohol, methyl bis(phenylmethyl)-benzene, sodium chloride, silicone, and a liquid metal.

36. A method of cooling a semiconductor heat source, comprising:
providing a heat exchanger having a channel for receiving a coolant, the channel having a first surface, an opposing second surface, and a mesh plug disposed therebetween for turbulently mixing the coolant within the channel, wherein the first surface of the channel is disposed proximate the semiconductor heat source; and
flowing a coolant through the channel.

37. The method of claim 36, further comprising:
providing an aperture formed through the first surface for receiving the semiconductor heat source therein.

38. The method of claim 36, further comprising:
recirculating the coolant through the channel using a pump.

39. The method of claim 36, further comprising:
providing a thermal interface between the semiconductor heat source and the first surface, the thermal interface comprising at least one of: a thermally conductive paste and a liquid metal thermal interface.

40. The method of claim 36, wherein the coolant comprises at least one of: water, a water-based liquid, glycol, ethylene glycol, polyethylene glycol, oil, hydrocarbon, hydrocarbon blends, alcohol, methyl bis(phenylmethyl)-benzene, sodium chloride, and silicone.

41. The method of claim 36, wherein the coolant is a liquid with a freezing point below that of water.

42. The method of claim 36, wherein the coolant is a liquid metal.

43. The method of claim 42, wherein the liquid metal comprises at least one of: mercury, gallium, indium, tin, and bismuth.
